(19) United States
(12) Patent Application Publication
(10) Pub. No.: US 2015/0002851 A1
(43) Pub. Date: Jan. 1, 2015

(54) MODE-LOCKED LASER LIGHT SOURCE DEVICE AND OPTICAL COHERENCE TOMOGRAPHY APPARATUS USING THE SAME

(71) Applicant: Akira Takada, Tokyo (JP)

(72) Inventor: Akira Takada, Tokyo (JP)

(73) Assignee: KABUSHIKI KAISHA TOPCON, Tokyo (JP)

(21) Appl. No.: 14/352,758

(22) PCT Filed: Sep. 14, 2012
(86) PCT No.: PCT/JP2012/073620

§ 371 Date: Apr. 18, 2014

(30) Foreign Application Priority Data
Oct. 24, 2011 (JP) 2011-232658

(51) Int. Cl. H01S 5/065; G01B 9/02; H01S 5/50

(52) U.S. Cl. CPC H01S 5/065; H01S 5/50; G01B 9/02091
USPC 356/479; 372/18

(57) ABSTRACT

This mode-locked laser light source device comprises a semiconductor optical amplifier wherein carriers are generated by the injection of an injection current thereinto, a pulse of laser light is amplified by the consumption of the carriers, and phase modulation equivalent to self-phase modulation depending on the pulse intensity of the laser light occurs due to a change in the density carriers; a sweep modulation unit which the oscillation wavelength of the pulse of the laser light emitted from the semiconductor optical amplifier is variable; a resonator which returns the pulse of the laser light modulated by the sweep modulation unit to the semiconductor optical amplifier to cause a laser oscillation phenomenon; and a dispersion compensator which is used in an anomalous dispersion region and changes the return time of the pulse of the laser light depending on the wavelength of the pulse of laser light guided in the resonator.

### TECHNICAL FIELD

The present invention relates to a mode-locked laser source device and an optical coherence tomography apparatus using the same in order to realize laser light with a narrow emission spectrum distribution (laser light with narrow linewidth).

### BACKGROUND ART

Conventionally, optical coherence tomography (OCT) is well-known (for example, Japanese Unexamined Patent Application Publication No. 2011-113048). In such optical coherence tomography, a wavelength-swept mode-locked laser source device is used as a laser light source.

Such an optical coherence tomography apparatus emits the laser light to an object to be measured, varying the wavelength of the laser light. Interference signal between the reflected laser light from a different depth of the object to be measured and the reference light is measured by an interferometer. By analyzing a frequency component of an interference signal, a tomography image of the object to be measured is obtained.

Wavelength-swept mode-locked laser source devices using a semiconductor optical amplifier (SOA) or a fiber Bragg grating (FBG) are also well-known (for example, Yuichi Nakazaki and Shinji Yamashita 11 May 2009/Vol. 17, No 10/OPTICSEXPRESS 8310 “Fast and Wide tuning range wavelength-swept fiber laser based on dispersion tuning and its application to dynamic FBG sensing”).

### RELATED ART DOCUMENT

### Patent Document

Patent Document 1: Japanese Unexamined Patent Application Publication No. 2011-113048 paragraphs [0001], [0002].

### Non Patent Document

Non Patent Document 1: Yuichi Nakazaki and Shinji Yamashita 11 May 2009/Vol. 17, No 10/OPTICSEXPRESS 8310 “Fast and Wide tuning range wavelength-swept fiber laser based on dispersion tuning and its application to dynamic FBG sensing”

### SUMMARY OF THE INVENTION

In an optical coherence tomography apparatus, a mode-locked laser light source device having a narrower spectral linewidth during sweeping is desirable in order to obtain excellent coherency during high-speed sweeping and measure a deep portion of the object. The present invention aims to resolve the above problem. It is an object of the present invention to provide a mode-locked laser light source device in which the emission wavelength is variable and the emission spectrum distribution is narrow.

A mode-locked laser light source device of the present invention comprises a semiconductor optical amplifier wherein carriers are generated by the injection of an injection current thereinto, a pulse of laser light is amplified by the consumption of the carriers, and phase modulation equivalent to self-phase modulation depending on the pulse intensity of the laser light occurs due to a change in the density of carriers; a sweep modulation unit which makes the oscillation wavelength of the pulse of the laser light emitted from the semiconductor optical amplifier variable; a resonator which returns the pulse of the laser light modulated by the sweep modulation unit to the semiconductor optical amplifier to cause a laser oscillation phenomenon; and a dispersion compensator which is used in an anomalous dispersion region and changes the return time of the pulse of the laser light depending on the wavelength of the pulse of laser light that is guided in the resonator.

Because the dispersion compensator built in the resonator is used in the anomalous dispersion region, a mode-locked laser light source device can be provided in which the emission wavelength is variable and the emission spectrum distribution is narrow during sweeping. It is preferable that such a mode-locked laser light source device be used in optical coherence tomography.

### BRIEF DESCRIPTION OF THE DRAWINGS

FIG. 1 is a schematic diagram of an optical system showing a main structure of a mode-locked laser source device in accordance with a first embodiment of the present invention.

FIG. 2A is a schematic perspective view explaining a concept of a dispersion compensator as shown in FIG. 1, and showing a linear chirped fiber Bragg grating as the dispersion compensator.

FIG. 2B shows an explanatory view illustrating a connecting method of the dispersion compensator as shown in FIG. 2A in an anomalous dispersion region.

FIG. 3 is a graph showing waveforms of pulses of laser light incident to and emitted from a semiconductor optical amplifier as shown in FIG. 1.

FIG. 4 is a graph showing a frequency chirp of the pulse of the laser light emitted from the semiconductor optical amplifier.

FIG. 5 is an exemplary graph of waveforms of pulses of the laser light emitted from the semiconductor optical amplifier in normal and anomalous dispersion regions.

FIG. 6 is a graph showing spectrum distributions of the pulses of the laser light emitted from the semiconductor optical amplifier in the normal and anomalous dispersion regions in the case of FIG. 5.

FIG. 7 is a schematic diagram of an optical system showing a main structure of a mode-locked laser source device in accordance with a second embodiment of the present invention.

FIG. 8 is a schematic diagram of an optical system showing a main structure of a mode-locked laser source device in accordance with a third embodiment of the present invention.

FIG. 9 is a schematic diagram of an optical system showing a main structure of a mode-locked laser source device in accordance with a fourth embodiment of the present invention.

### DESCRIPTION OF THE EMBODIMENTS

### First Embodiment

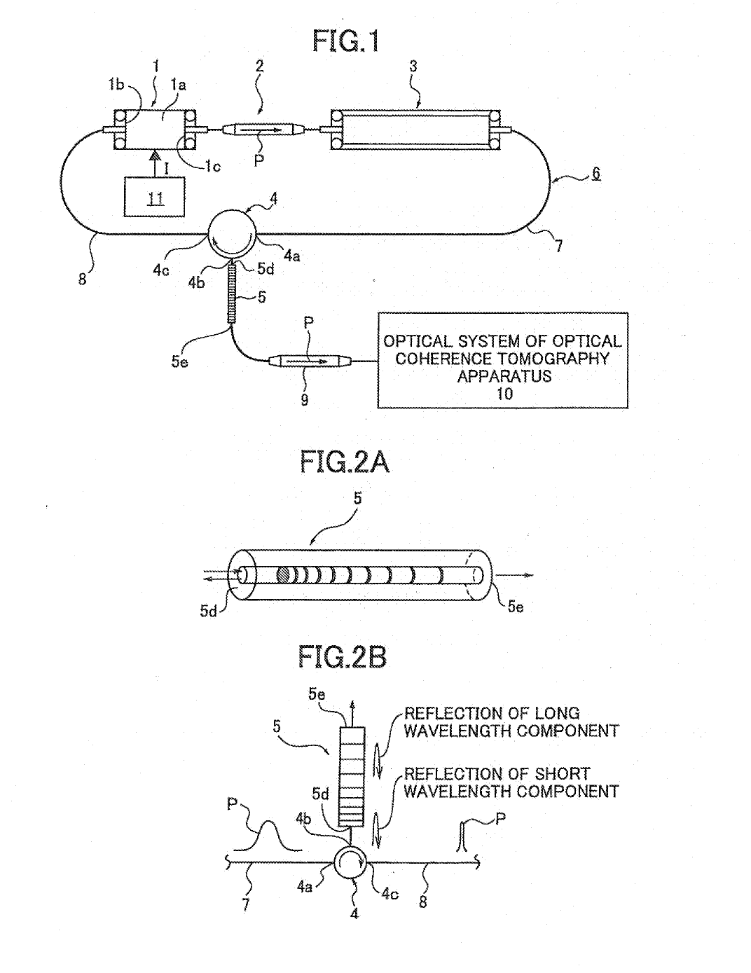

With reference to the drawings, a mode-locked laser light source device according to a first embodiment of the present invention will be now described. FIG. 1 is a schematic diagram showing the main structure of the optical coherence tomography apparatus having the mode-locked laser source device in accordance with the first embodiment of the present invention.

In FIG. 1, reference numerals 1, 2, 3, 4, and 5 represent a semiconductor optical amplifier (SOA), an optical isolator, a sweep modulation unit, a circulator, and a dispersion compensator, respectively. A ring resonator 6 includes the semiconductor optical amplifier 1, the optical isolator 2, the sweep modulation unit 3, the circulator 4, and the dispersion compensator 5.

The semiconductor optical amplifier 1 includes a waveguide structure 1a. An incident end face 1b is one end face of the waveguide structure 1a. A radiation end face 1c is the other end face of the waveguide structure 1a. Carriers are generated in the waveguide structure 1a by injecting an injecting current I to the waveguide structure 1a. The carriers are consumed by a stimulated emission phenomenon due to the light pulse from the incident end face 1b of the waveguide structure 1a such that the pulse of laser light in the semiconductor optical amplifier 1 is amplified, and a pulse of the laser light is emitted from the radiation end face 1c. An SOA module having a 3-dB gain linewidth 80.6 nm is used as the semiconductor optical amplifier 1.

The pulse of the laser light P emitted from the incident end face 1c is guided to the sweep modulation unit 3 via the optical isolator 2 as an optical device in which light is transmitted only in one direction and returned light is cutoff. A polarization-dependent isolator and polarization-independent isolator are used for the light isolator 2.

A device with a function having an intensity modulation or a phase modulation of the pulse of the laser light P which is incident in the sweep modulation unit 3 can be used as the sweep modulation unit 3. In the first embodiment, an Electro-Optic Modulator (EOM) is used.

The circulator 4 has three ports. A first port 4a of the circulator 4 is connected to a radiation guide fiber 7 guiding the pulse of the laser light P emitted from the sweep modulation unit 3.

A second port 4b of the circulator 4 is connected to the dispersion compensator 5. A linear chirped fiber Bragg grating (LC-FBG), as conceptually shown in FIGS. 2A and 2B, is used as the dispersion compensator 5.

In this linear chirped fiber Bragg grating, the period of grating varies such that a reflective position of a low frequency component of the pulse is linearly different to that of high frequency component. The linear chirped fiber Bragg grating includes a diffraction grating in the fiber.

The linear chirped fiber Bragg grating having characteristics in which a chirp rate is 10 nm/cm, a peak reflectivity is 70%, and a 3-dB gain linewidth is 60 nm (i.e., from 1520 nm to 1580 nm), is used.

The linear chirped fiber Bragg grating has characteristics of both normal dispersion and anomalous dispersion. Connecting method in the second port 4b of the circulator 4 of the linear chirped fiber Bragg grating is determined whether the linear chirped fiber Bragg grating is used in the normal or anomalous dispersion regions.

In other words, the linear chirped fiber Bragg grating can also be used in both the normal dispersion region where the pulse light with a long wavelength component is reflected, and that of a short wavelength component is subsequently reflected, and in the anomalous dispersion region where the pulse light with a short wavelength component is reflected, and that of a long wavelength component is subsequently reflected.

In the first embodiment, since the pulse light is used in the anomalous dispersion region in which the pulse light with the short wavelength component is reflected, and that of the long wavelength component is subsequently reflected, the linear chirped fiber Bragg grating is connected to the second port 4b. In FIGS. 1, 2A, and 2B, reference numerals 5d and 5e denote incident and transmission end faces, respectively.

A third port 4c of the circulator 4 is connected to a feedback guide fiber 8 which is fed back the laser pulse light reflected from the linear chirped fiber Bragg grating to the semiconductor optical amplifier 1.

The pulse of the laser light P emitted from the transmit end face 5e of the linear chirped fiber Bragg grating is introduced to an optical system 10 of the subsequent optical coherence tomography apparatus via the isolator 9. In the first embodiment, the above pulse of the laser light P is connected to an interferometer and an oscilloscope (not shown) for evaluating experiment results.

A wavelength linewidth of the laser light (pulse light) P in the optical system 10 of the optical coherence tomography apparatus is about 1 μm. However, in the first embodiment, a different wavelength linewidth of the laser light (pulse light) P is used for the experiment.

A resonator length L of the ring resonator 6 is about 2.7 m for the use of the high-speed sweeping. Because the ring resonator 6 has a dispersion property, the resonant frequency f of m-th order of the ring resonator 6 is represented by the below formula.

f(λ)=m·c/{n·(L+2Lf(λ))}.

m is a positive integer, f(λ) is an m-th order resonant frequency for the wavelength λ, c is a light velocity in vacuum, Lf(λ) is a length of the linear chirped Bragg grating, and n is an equivalent index of refraction of the incident guide fiber, the feedback guide fiber, and the linear chirped Bragg grating. The ring resonator 6 comprises the incident guide fiber 7, the feedback guide fiber 8, and the linear chirped Bragg grating. In the first embodiment, the index of refraction n is constant.
Here, Lf(λ0) is considered to be 0. The resonant frequency f(λ0) of the wavelength λ0 is represented by the below formula,

f(λ0)=(m·c)/(n·L).

The resonant frequency f(λ1) of the wavelength λ1 is represented by the below formula,

f(λ1)=m·c/{n·(L+2(λ1−λ0)/A)},

where A is a chirp rate.

By approximating the above formula using the Taylor expansion, a difference of the resonant frequency between the two wavelengths Δf can be represented by the below formula,

Δλ=(L·A)·Δf/2f(λ0),

where Δλ=λ1−λ0.

With reference to the above formula, it is understood that an emission wavelength can be variable by varying the intensity modulation frequency in the ring resonator 6. Since dispersion media exist in the resonator, a time for propagating in the resonator is different, depending on the wavelength. When intensity-modulating to the light in the resonator, the wavelength coincident to the modulation frequency is only resonant in the resonator.

A Free Spectral Range (FSR), which is a wavelength sweep width, is represented by the below formula,

FSR=(c·A)/(2·n·f).

A constant current I from an injection current control unit 11 is injected to the semiconductor optical amplifier 1. The carriers are generated by injecting the current I. The pulse of laser light P is amplified by the consumption of the carriers, and phase modulation equivalent to self-phase modulation depending on the pulse intensity of the laser light occurs due to a change in the density of carriers.

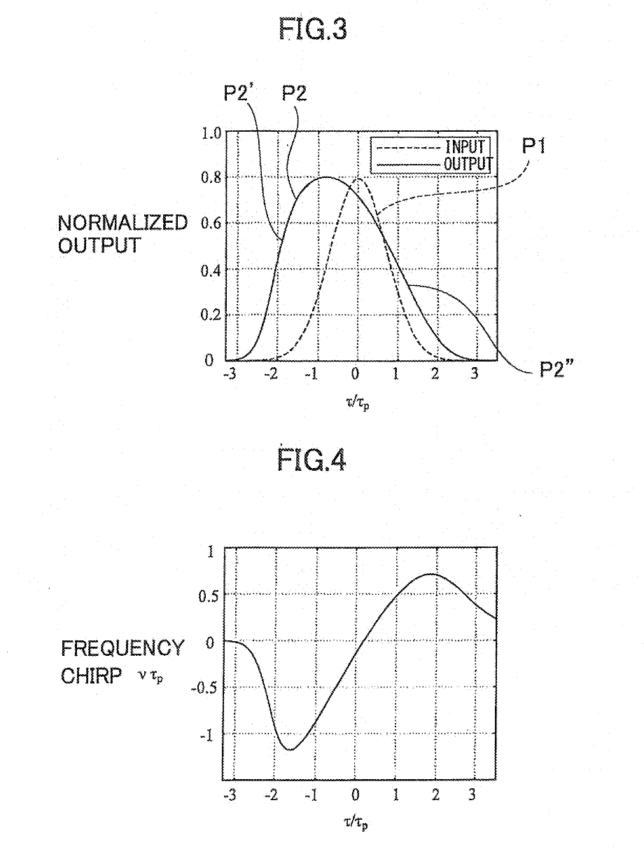

FIG. 3 shows waveforms of the pulse of the laser light P incident in the incident end face 1b of the semiconductor optical amplifier 1, and the pulse of the laser light P emitted from the radiation end face 1c of the semiconductor optical amplifier 1. In FIG. 3, the numeral P1 is a pulse-waveform of the laser light P incident in the incident end face 1b. The numeral P2 is a pulse-waveform of the laser light P emitted from the radiation end face 1c. Horizontal and vertical axes denote time and the normalized intensity of the pulse of the laser light P, respectively.

In FIG. 3, the time axis is normalized by using an incident pulse width tip to the semiconductor optical amplifier 1 of the laser light (pulse light) P incident in the incident end face 1b. In FIG. 3, it is considered that the pulse waveform P1 of the laser light P incident in the incident end face 1b of the semiconductor optical amplifier 1 exhibits a normal distribution against the time axis. The pulse waveform P2 of the laser light P emitted from the radiation end face 1c of the semiconductor optical amplifier 1 is depicted.

When the phase modulation equivalent to the self-phase modulation depending on the pulse intensity of the laser light occurs in the semiconductor optical amplifier 1, the frequencies are decreasing and increasing (the wavelength is longer and shorter) in the rise-up and fall-down portions of the pulses, respectively. This frequency shift between the rise-up portion and the fall-down portion is known as a chirp.

FIG. 4 is a graph for aiding visual understanding of the frequency chirp. Horizontal and vertical axes denote time and a frequency chirp, respectively. Because the rise-up portion P2′ of the pulse waveform P2 (refer to FIG. 3) is shifted to the—direction as a reference value defines 0 in FIG. 4, the pulse exhibits red shift. Since the fall-down portion P2″ of the pulse waveform P2 is shifted to the + direction as a reference value defines 0, the pulse exhibits blue shift.

In the case of such a phase modulation equivalent to the Self Phase Modulation (SPM) occurring, because a propagation velocity of a frequency component in the rise-up portion having a long wavelength P2′ is high, and that of the frequency component in the fall-down portion having a short wavelength P2″ is slow, the pulse width on the time axis is spread. Because the sign of the phase modulation equivalent to the Self Phase Modulation (SPM) is the same as that of the phase modulation generated by the normal dispersion on the time axis, the wavelength width of the pulse is spread by affecting the phase modulation equivalent to the Self Phase Modulation (SPM).

The propagation velocities of the rise-up and fall-down portions of the pulse waveforms P2′ and P2″ are slow and high in the anomalous dispersion region, respectively. Thus, the circulate time of the rise-up portion P2′ having the long wavelength is long and the circulate time of the fall-down portion P2″ having the short wavelength is short.

Even in the anomalous dispersion region, the pulse width becomes wider due to the wavelength dispersion. The phase modulation equivalent to the Self Phase Modulation (SPM) in the semiconductor optical amplifier 1 functions to compress the pulse of the laser light.

Because the sign of the phase modulation equivalent to the Self Phase Modulation (SPM) is different to that of the phase modulation generated by the anomalous dispersion on the time axis, the wavelength spreading by the phase modulation equivalent to the Self Phase Modulation (SPM) can be restricted. Then, by adjusting amounts of the anomalous dispersion and the phase modulation equivalent to the Self Phase Modulation (SPM), the spectral distribution can be varied, arbitrarily.

When the spreading of the pulse of the laser light by the wavelength dispersion in the anomalous dispersion region is balanced to the effect of the pulse compression of the laser light by a nonlinear effect of the semiconductor optical amplifier 1, a similar effect of generating light soliton, which the pulse of the laser light propagates while retaining the waveform, occurs.

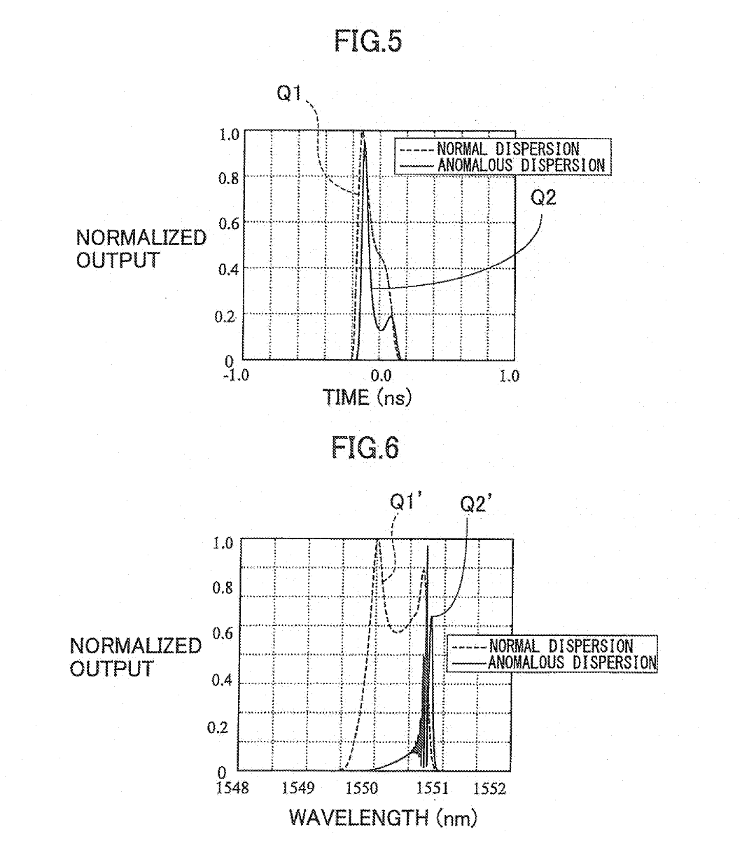

FIG. 5 shows pulse waveforms of the laser light in the normal and anomalous dispersion regions. In FIG. 5, the horizontal and vertical axes denote time and normalized intensity of the pulse of the laser light, respectively. The numeral Q1 shows the radiation pulse waveform in the normal dispersion region. The numeral Q2 shows the radiation pulse waveform in the anomalous dispersion region.

FIG. 6 shows a wavelength property of both radiation pulse waveforms in FIG. 5. The numeral Q1′ shows a wavelength property (spectral distribution) in the case of using the dispersion compensator 5 in the normal dispersion region. The numeral Q2′ shows a wavelength property (spectral distribution) in the case of using the dispersion compensator 5 in the anomalous dispersion region.

From FIG. 6, it is obvious that the wavelength property Q2′ in the case of using the dispersion compensator 5 in the anomalous dispersion region realizes a narrow spectral distribution (narrow width), compared with the wavelength property Q1′ in the case of using the dispersion compensator 5 in the normal dispersion region.

When the predetermined current I is injected in this mode-locked laser light source device, the pulse of the laser light P is emitted from the radiation end face 1c of the semiconductor optical amplifier 1. When the sweep modulation unit 3 is operated so as to change the pulse intensity of the laser light P, the light having the pulse intensity of this modulated laser light P is guided to the dispersion compensator 5 via the radiation guide fiber 7 and the circulator 4.

The laser light P, in which the long wavelength component is subsequently reflected after the short wavelength component is reflected in this dispersion compensator 5, is returned to the semiconductor optical amplifier 1 via the feedback guide fiber 8. This laser light P is circulated in the ring resonator 6. The wavelength dispersion using the dispersion compensator 5 in the anomalous dispersion region and the pulse compression effect of the semiconductor optical amplifier 1 generates an effect which is similar to the light soliton, so as to realize a narrow linewidth of the spectral distribution.

The pulse of the laser light with the narrow linewidth is emitted from the transmission end face 5e of the dispersion compensator 5 and is guided to the optical system 10 of the subsequent optical coherence tomography apparatus via the isolator 9. As mentioned above, the spectral distribution is variable by adjusting the amounts of the anomalous dispersion and the phase modulation equivalent to the SPM.

When the intensity of the phase modulation equivalent to the Self Phase Modulation (SPM) is approximated to that of the phase modulation generated by the anomalous dispersion, the width of the spectral distribution is narrower. When the intensity of the phase modulation equivalent to the Self Phase Modulation (SPM) is distant from that of the phase modulation generated by the anomalous dispersion such that the difference between the intensity of the phase modulation equivalent to the Self Phase Modulation (SPM) and that of the phase modulation generated by the anomalous dispersion is larger, the width of the spectral distribution is wider.

The intensity of the phase modulation equivalent to the Self Phase Modulation (SPM) can be varied by changing the following elements. A first element is the pulse intensity of the laser light P incident in the semiconductor optical amplifier 1. The larger the pulse intensity of the laser light P, the larger the phase modulation equivalent to the Self Phase Modulation (SPM). This pulse intensity can be changed by varying a modulation waveform of the sweep modulation unit 3 and the reflectivity of the dispersion compensator 5 and so on.

A second element is the injecting current I to the semiconductor optical amplifier 1. The higher the injecting current I, the more the phase modulation equivalent to the SPM. A third element is the kind of the semiconductor optical amplifier 1. Compared with the semiconductor optical amplifiers having a quantum well and a quantum dot, the phase modulation equivalent to the SPM is generated more frequently in the latter case. In the case of the phase modulation generated by the anomalous dispersion, the intensity of the phase modulation can be varied by changing the dispersion compensator 5.

In the first embodiment, the sweep modulation unit 3 is used as the intensity modulator. A phase modulator may also be used. It is possible that the sweep modulation unit 3 is disposed between the radiation end face 1c of the semiconductor optical amplifier 1 and the third port 4c of the circulator 4, and the optical isolator 2 is omitted.

### Second Embodiment

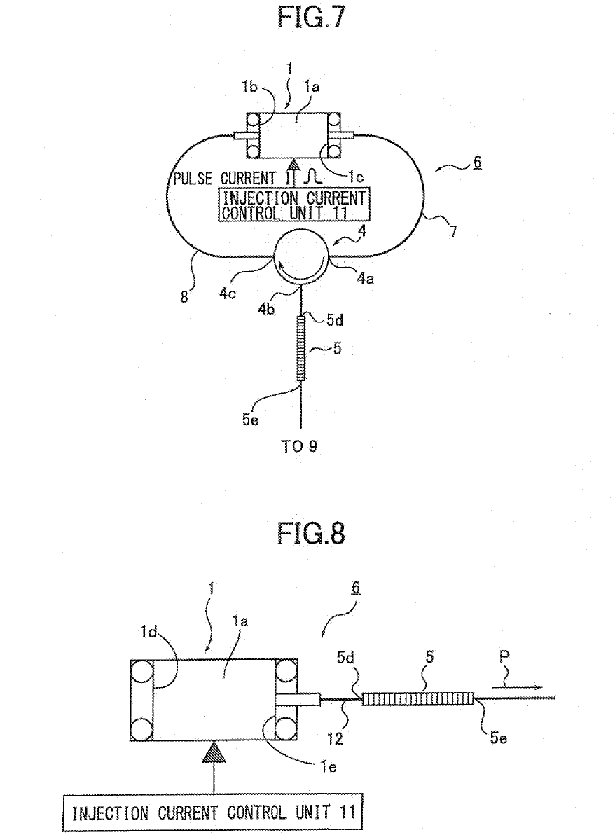

FIG. 7 shows the mode-locked laser source device in accordance with the second embodiment. In the second embodiment, the sweep modulation unit 3 includes the injection current control unit 11 pulse-controlling the injection current I to the semiconductor optical amplifier 1. Because residuals of the structure components are the same as those of the first embodiment, structural components which are the same as the first embodiment are given the same reference numerals and a detailed description is omitted.

In the second embodiment, a pulse current is injected to the semiconductor optical amplifier 1 as the injection current I. The modulation is generated by varying the pulse-waveform, period, pulse-width, and pulse current amount of this injection current I.

### Third Embodiment

FIG. 8 shows the mode-locked laser source device in accordance with the third embodiment. In the third embodiment, the ring resonator 6 includes a guide fiber 12 which guides and is fed back to the pulse of the laser light emitted from an incident and radiation end face 1e opposed to the reflective end face 1d of the semiconductor optical amplifier 1.

This guide fiber 12 is connected to the dispersion compensator 5. This dispersion compensator 5 is also used in the anomalous dispersion region. The pulse of the laser light P is also emitted from the transmission end face 5e. The linear chirped fiber Bragg grating is used as the dispersion compensator 5.

### Fourth Embodiment

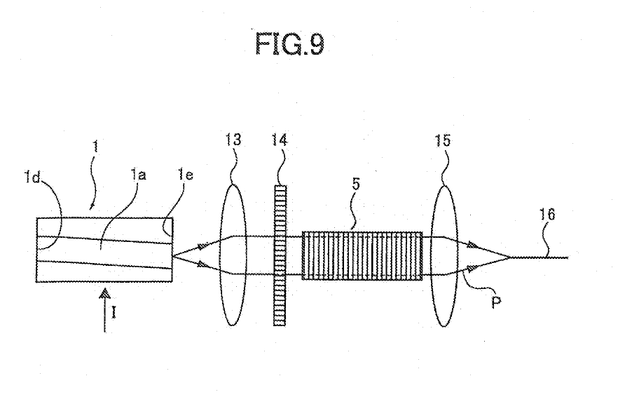

FIG. 9 shows the fourth embodiment of the mode-locked laser light source device. In the fourth embodiment, a volume hologram, which is an alternative to the linear chirped Bragg grating of the third embodiment, is used as the dispersion compensator 5.

In the semiconductor optical amplifier (SOA) in accordance with the fourth embodiment, the reflectivity is restricted to less than or equal to 0.001% because the incident and radiation end face 1e is inclined to the optical path of the waveguide structure 1a.

The pulse of the laser light P emitted from the incident and radiation end face 1e forms a parallel light flux by the collimating lens 13, and is guided to the polarizer 14. The pulse of the laser light P is introduced to a convergent lens 15 after dispersing the pulse in the anomalous dispersion region. Then, the pulse of the laser light is incident in the guide fiber 16, and is guided to the subsequent optical system 10 of the optical coherence tomography apparatus. The polarizer 14 can be omitted.

In the embodiments of the present invention, the linear chirped fiber Bragg grating and the volume hologram are used as the dispersion compensator 5. However, the present invention is not limited to the above members. A chirp mirror may also be used.

### CROSS-REFERENCE TO RELATED APPLICATION

This application claims priority from Japanese Patent Application No. 232586/2011 filed on Oct. 24, 2011, the disclosure of which is herein incorporated by reference.
1 semiconductor optical amplifier
3 sweep modulation unit
4 circulator
5 dispersion compensator
6 ring resonator

1. A mode-locked laser light source device, comprising:
a semiconductor optical amplifier wherein carriers are generated by the injection of an injection current thereinto, a pulse of laser light is amplified by the consumption of the carriers, and phase modulation equivalent to self-phase modulation depending on the pulse intensity of the laser light occurs due to a change in the density of carriers;
a sweep modulation unit which the oscillation wavelength of the pulse of the laser light emitted from the semiconductor optical amplifier is variable;
a resonator which returns the pulse of the laser light modulated by the sweep modulation unit to the semiconductor optical amplifier to cause a laser oscillation phenomenon; and
a dispersion compensator which is used in an anomalous dispersion region and changes the return time of the pulse of the laser light depending on the wavelength of the pulse of laser light that is guided in the resonator.

2. The mode-locked laser light source device according to claim 1, further comprising:
an incident guide fiber guiding the pulse of the laser light emitted from an incident end face of the semiconductor optical amplifier; and
a feedback guide fiber guiding the pulse of the laser light propagating the incident guide fiber to the incident end face of the semiconductor optical amplifier, wherein the incident guide fiber and the feedback guide fiber are connected to first and second ports, respectively, the dispersion compensator is connected between the first and second ports, and the pulse of the laser light is emitted from the dispersion compensator.

3. The mode-locked laser light source device according to claim 1, wherein the resonator comprises a guide fiber which guides and is fed back to the pulse of the laser light emitted from an incident and radiation end face opposed to a reflective end face of the semiconductor optical amplifier, the dispersion compensator is connected to the guide fiber, and the pulse of the laser light is emitted from the dispersion compensator.

4. The mode-locked laser light source device according to claim 1, wherein the sweep modulation unit comprises a modulator intensity-modulating or phase-modulating the pulse of the laser light.

5. The mode-locked laser light source device according to claim 1, wherein the sweep modulation unit comprises an injection current control unit pulse-controlling the injection current to the semiconductor optical amplifier.

6. The mode-locked laser light source device according to claim 1, wherein the dispersion compensator is a linear chirped fiber Bragg grating, a chirp minor, or a volume hologram.

7. An optical coherence tomography apparatus, comprising the mode-locked laser light source device according to claim 1.
